(19) United States
(12) Patent Application Publication
(10) Pub. No.: US 2025/0096162 A1
(43) Pub. Date: Mar. 20, 2025

(54) SEMICONDUCTOR STRUCTURE AND MANUFACTURING METHOD THEREFOR

(71) Applicant: CXMT CORPORATION, Hefei (CN)

(72) Inventors: You FU, Hefei (CN); Shuangshuang WU, Hefei (CN); TZUNG-HAN LEE, Hefei (CN); CHIH-CHENG LIU, Hefei (CN); Xiaolong CHEN, Hefei (CN)

(21) Appl. No.: 18/963,499

(22) Filed: Nov. 28, 2024

Related U.S. Application Data
(63) Continuation of application No. PCT/CN2024/102365, filed on Jun. 28, 2024.

(30) Foreign Application Priority Data
Jul. 14, 2023 (CN) 202310868012.5

(51) Int. Cl. H01L 23/64; H01L 21/48; H01L 23/498

(52) U.S. Cl. CPC H01L 23/642; H01L 21/4846; H01L 23/49838

(57) ABSTRACT

A semiconductor structure and a manufacturing method therefor are disclosed. The semiconductor structure includes an interposer, where the interposer includes a deep trench capacitor array and an isolation structure. The deep trench capacitor array includes multiple deep trench capacitors, and the isolation structure at least partially surrounds a deep trench capacitor on the outmost edge side of the deep trench capacitor array.

### CROSS-REFERENCES TO RELATED APPLICATIONS

This application is a continuation of International Patent Application No. PCT/CN2024/102365, filed on Jun. 28, 2024, which claims the benefit of Chinese Patent Application No. 202310868012.5, titled “SEMICONDUCTOR STRUCTURE AND MANUFACTURING METHOD THEREFOR”, filed with the China National Intellectual Property Administration (CNIPA) on Jul. 14, 2023, the disclosures of which are incorporated herein by reference in their entireties.

### TECHNICAL FIELD

Embodiments of the present disclosure relate to the field of semiconductor technologies, and in particular, to a semiconductor structure and a manufacturing method therefor.

### BACKGROUND

With development of semiconductor technologies, packaging different types of chips through an interposer gradually becomes a development trend of packaging technologies. In a related technology, a deep trench capacitor (DTC) is usually disposed in the interposer as a decoupling capacitor to reduce signal noise and leakage between adjacent semiconductor devices coupled to the interposer. However, there is relatively large parasitic capacitance between the deep trench capacitor and an another device on the interposer, which easily causes interference to the another device.

### SUMMARY

According to a first aspect of the embodiments of the present disclosure, a semiconductor structure is provided and includes an interposer, where the interposer includes a deep trench capacitor array and an isolation structure. The deep trench capacitor array includes multiple deep trench capacitors, and the isolation structure at least partially surrounds a deep trench capacitor on an outmost edge side of the deep trench capacitor array.

According to a second aspect of the embodiments of the present disclosure, a manufacturing method for a semiconductor structure is provided and includes the steps as follows: An interposer is provided. An initial deep trench capacitor array structure is formed in the interposer, where the initial deep trench capacitor array structure includes multiple initial deep trench capacitor structures. A first etching is performed on the initial deep trench capacitor array structure to expose a first electrode layer on a periphery of an initial deep trench capacitor structure on the outmost edge side of the initial deep trench capacitor array structure to form an intermediate deep trench capacitor array structure. A second etching is performed on the intermediate deep trench capacitor array structure to etch a side that is of the first electrode layer being exposed and that is away from the initial deep trench capacitor structure on the outmost edge side to form an isolation trench and cut off adjacent capacitor cells in the intermediate deep trench capacitor array structure to form a deep trench capacitor array. An isolation material is filled in the isolation trench to form an isolation structure, where the isolation structure at least partially surrounds a deep trench capacitor on the outmost edge side of the deep trench capacitor array.

The details of one or more embodiments of the present disclosure are set forth in the following accompanying drawings and description.

### BRIEF DESCRIPTION OF DRAWINGS

To describe the technical solutions in the embodiments of the present disclosure more clearly, the following briefly describes the accompanying drawings required for the embodiments. Clearly, the accompanying drawings in the following description show merely some embodiments of the present disclosure, and a person of ordinary skill in the art may still derive other drawings from these accompanying drawings without creative efforts.

FIG. 1 is a schematic diagram 1 of a vertical cross-section of a semiconductor structure according to an embodiment of the present disclosure;

FIG. 2 is a schematic top view of a semiconductor structure according to an embodiment of the present disclosure;

FIG. 3 is an enlarged schematic diagram of a region in a dashed-line box in FIG. 2;

FIG. 4 is a microscopic image of a semiconductor structure according to an embodiment of the present disclosure;

FIG. 5 is a schematic diagram 2 of a vertical cross-section of a semiconductor structure according to an embodiment of the present disclosure;

FIG. 6 is a schematic flowchart of a manufacturing method for a semiconductor structure according to an embodiment of the present disclosure;

FIG. 7 is a schematic structural diagram 1 of a semiconductor structure in a manufacturing process according to an embodiment of the present disclosure;

FIG. 8 is a schematic structural diagram 2 of a semiconductor structure in a manufacturing process according to an embodiment of the present disclosure;

FIG. 9 is a schematic structural diagram 3 of a semiconductor structure in a manufacturing process according to an embodiment of the present disclosure;

FIG. 10 is a schematic structural diagram 4 of a semiconductor structure in a manufacturing process according to an embodiment of the present disclosure;

FIG. 11 is a schematic structural diagram 5 of a semiconductor structure in a manufacturing process according to an embodiment of the present disclosure;

FIG. 12 is a schematic structural diagram 6 of a semiconductor structure in a manufacturing process according to an embodiment of the present disclosure;

FIG. 13 is a schematic structural diagram 7 of a semiconductor structure in a manufacturing process according to an embodiment of the present disclosure;

FIG. 14 is a schematic structural diagram 8 of a semiconductor structure in a manufacturing process according to an embodiment of the present disclosure;

FIG. 15 is a schematic structural diagram 9 of a semiconductor structure in a manufacturing process according to an embodiment of the present disclosure;

FIG. 16 is a schematic structural diagram 1 of a semiconductor structure in a manufacturing process according to a related technology;

FIG. 17 is a schematic structural diagram 2 of a semiconductor structure in a manufacturing process according to a related technology;

FIG. 18 is a schematic structural diagram 3 of a semiconductor structure in a manufacturing process according to a related technology;

FIG. 19 is a schematic structural diagram 4 of a semiconductor structure in a manufacturing process according to a related technology;

FIG. 20 is a schematic structural diagram 5 of a semiconductor structure in a manufacturing process according to a related technology;

FIG. 21 is a schematic structural diagram 6 of a semiconductor structure in a manufacturing process according to a related technology;

FIG. 22 is a schematic structural diagram 7 of a semiconductor structure in a manufacturing process according to a related technology;

FIG. 23 is a schematic structural diagram 8 of a semiconductor structure in a manufacturing process according to a related technology; and

FIG. 24 is a schematic structural diagram 9 of a semiconductor structure in a manufacturing process according to a related technology.

### DETAILED DESCRIPTION

The technical solutions of the present disclosure are further described below in detail with reference to the accompanying drawings and the embodiments. Although example implementations of the present disclosure are shown in the accompanying drawings, it should be understood that the present disclosure may be implemented in various forms without being limited by the implementations described herein. Instead, these implementations are provided to develop a more thorough understanding of the present disclosure and to fully convey the scope of the present disclosure to a person skilled in the art.

In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not to exact scale, and are merely intended to conveniently and clearly assist in describing the embodiments of the present disclosure.

It may be understood that meanings of “on”, “over”, and “above” in the present disclosure should be understood in the broadest sense, so that “on” means that it is “on” something with no intermediate feature or layer (that is, directly on something), and further includes the meaning that it is “on” something with an intermediate feature or layer.

In the embodiments of the present disclosure, the terms “first”, “second”, “third”, and the like are intended to distinguish between similar objects but do not necessarily indicate a specific order or sequence.

In the embodiments of the present disclosure, the term “layer” refers to a material part including a region having a thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between the top surface and the bottom surface of the continuous structure, or the layer may be located between any horizontal surface pair at the top surface and the bottom surface of the continuous structure. The layer may extend horizontally, vertically, and/or along an inclined surface. Multiple sublayers may be included in the layer.

It should be noted that the technical solutions described in the embodiments of the present disclosure may be arbitrarily combined when there is no conflict.

With the development of semiconductor technologies, conventional two-dimensional packaging can no longer meet requirements of the industry. Therefore, a vertical interconnect stacked packaging manner based on a through silicon via (TSV) technology is to package different types of chips with a Si interposer. The packaging manner has key technical advantages of short-distance interconnection and high-density integration, and gradually leads development of the packaging technology.

In a related technology, a deep trench capacitor (DTC) is usually disposed in an interposer to serve as a decoupling capacitor to reduce signal noise and leakage between adjacent semiconductor devices coupled to the interposer. However, because the deep trench capacitor array on the interposer does not have an isolation structure, the deep trench capacitor array has a relatively large keep-out-zone (KOZ, where the keep-out-zone refers to a region in which no circuit element such as a transistor is disposed around the deep trench capacitor array), and there is relatively large parasitic capacitance between the deep trench capacitor array and another device on the interposer (including between deep trench capacitor arrays), which easily causes interference to the another device.

Based on this, the following technical solutions are proposed in the present disclosure.

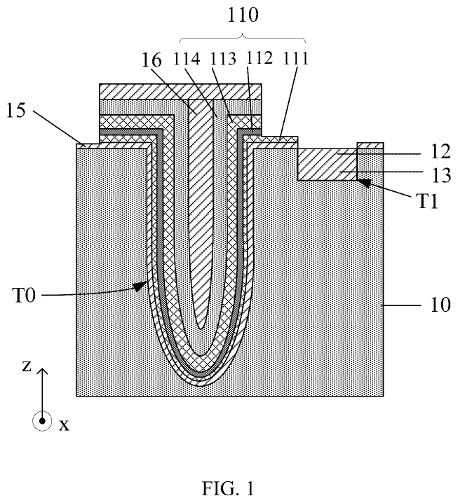

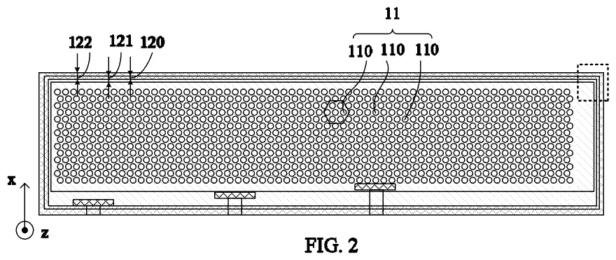

The embodiments of the present disclosure provide a semiconductor structure. FIG. 1 is a schematic diagram of a vertical cross-section of a semiconductor structure according to an embodiment of the present disclosure, FIG. 2 is a schematic top view of a semiconductor structure according to an embodiment of the present disclosure, and FIG. 3 is an enlarged schematic diagram of a region in a dashed-line box in FIG. 2.

Referring to FIG. 1, the semiconductor structure includes an interposer 10, where the interposer 10 includes a deep trench capacitor array 11 (as shown in FIG. 2) and an isolation structure 12.

The deep trench capacitor array 11 includes multiple deep trench capacitors 110, and the isolation structure 12 at least partially surrounds a deep trench capacitor 110 on an outmost edge side of the deep trench capacitor array 11 (that is, on a periphery of the deep trench capacitor array).

It should be noted that a first direction x shown in FIG. 1 and a vertical direction z shown in FIG. 2 are directions perpendicular to a paper surface. In addition, to clearly illustrate content in this embodiment, FIG. 1 shows only a position relationship between the deep trench capacitor 110 on the outmost edge side of the deep trench capacitor array 11 and the isolation structure 12. Details are not described later.

In this embodiment of the present disclosure, referring to FIG. 1, the interposer 10 is a channel for transferring an electrical signal between multiple chips in a package. The interposer 10 may implement interconnection between chips, or may implement interconnection to a packaging substrate, and serve as a bridge between multiple dies and a circuit board. For example, the interposer 10 may connect a memory chip (e.g., a dynamic random access memory (DRAM)) to a logic chip (e.g., a central processing unit (CPU) or a graphics processing unit (GPU)). The material of the interposer 10 may be a material such as silicon, polysilicon, germanium, silicon germanium, or silicon carbide.

In some embodiments of the present disclosure, referring to FIG. 2, projections of the multiple deep trench capacitors 110 on the upper surface of the interposer 10 in the vertical direction z are arranged in a shape of a regular hexagon. Specifically, projections of six adjacent deep trench capacitors 110 on a plane of the interposer 10 are arranged in a shape of a regular hexagon, one deep trench capacitor 110 is disposed at each vertex angle of the regular hexagon, and one deep trench capacitor 110 is disposed in the center of the regular hexagon. In other words, the deep trench capacitors 110 are arranged in a hexagonal closest packed (HCP) structure. It may be understood that the multiple deep trench capacitors 110 are arranged in the hexagonal closest packed structure, so that closely arranged deep trench capacitor arrays 11 can be obtained, thereby increasing a capacitance value of the deep trench capacitor array 11.

In some embodiments of the present disclosure, referring to FIG. 1, the deep trench capacitor 110 includes a first electrode layer 111, a capacitor dielectric layer 112, a second electrode layer 113, and a conductive layer 114. The first electrode layer 111 covers an inner surface of a deep trench T0 in the interposer 10 and extends to the upper surface of the interposer 10, the capacitor dielectric layer 112 covers the first electrode layer 111, the second electrode layer 113 covers the capacitor dielectric layer 112, and the conductive layer 114 covers the second electrode layer 113.

In some other embodiments, the deep trench capacitor may include multiple electrode layers and multiple capacitor dielectric layers that are alternately stacked, for example, the deep trench capacitor may be a double-sided deep trench capacitor. In this way, a capacitance value of the deep trench capacitor can be increased.

It should be noted that, the deep trench T0 is a trench in which the deep trench capacitor 110 in the interposer 10 is located, and the deep trench T0 has a relatively high aspect ratio. For example, the aspect ratio of the deep trench T0 may be 10, 15, or 20.

In this embodiment of the present disclosure, referring to FIG. 1, the materials of the first electrode layer 111, the second electrode layer 113, and the conductive layer 114 may be at least one of conductive materials such as doped silicon, polysilicon, copper, tungsten, aluminum, copper alloy, titanium, and titanium nitride. Specifically, the materials of the first electrode layer 111 and the second electrode layer 113 are titanium nitride, and the material of the conductive layer 114 is polysilicon. The material of the capacitor dielectric layer 112 may be at least one of insulating materials such as aluminum oxide (Al₂O₃) and zirconium oxide (ZrO). The capacitor dielectric layer 112 may further include another insulating material with a relatively high dielectric constant (high-k), e.g., a material with a dielectric constant greater than 3.9.

In this embodiment of the present disclosure, referring to FIG. 1, the isolation structure 12 at least partially surrounds the deep trench capacitor 110 on the outmost edge side of the deep trench capacitor array 11. In other words, the isolation structure 12 may partially surround the deep trench capacitor 110 on the outmost edge side of the deep trench capacitor array 11, or may completely surround the deep trench capacitor 110 on the outmost edge side of the deep trench capacitor array 11. An example in which the isolation structure 12 completely surrounds the deep trench capacitor 110 on the outmost edge side of the deep trench capacitor array 11 is employed below for description.

In some embodiments of the present disclosure, referring to FIG. 1, the isolation structure 12 includes a first isolation structure 13, an isolation trench T1 is disposed in the interposer 10, and the first isolation structure 13 is located in the isolation trench T1.

In some embodiments of the present disclosure, referring to FIG. 1, an aspect ratio of the isolation trench T1 is 2 to 10, including endpoint values. For example, the aspect ratio of the isolation trench T1 may be 2, 5, 7, or 10.

It should be noted that a size of the isolation trench T1 may be determined based on an actual requirement. Consideration factors mainly include a quantity, a size, and a layout of deep trench capacitors, a capacitance value, an operating voltage, a peripheral circuit endurance range, a distance between a device that needs to be isolated and the deep trench capacitor array, and the like. For example, when the distance between the device that needs to be isolated and the deep trench capacitor array 11 is shorter, the isolation trench T1 may be set to be deeper and wider.

In some embodiments of the present disclosure, referring to FIG. 1, on a cross-section perpendicular to the first direction x, a cross-sectional shape of the first isolation structure 13 may be a rectangle, a trapezoid, an inverted trapezoid, or an oval, and the first direction x is perpendicular to the vertical direction z. The cross-sectional shape of the first isolation structure 13 is not specifically limited herein. An example in which the cross-sectional shape of the first isolation structure 13 is a rectangle is employed below for description.

In this embodiment of the present disclosure, referring to FIG. 1, the material of the first isolation structure 13 may include insulating materials such as an oxide, a nitride, or a nitrogen oxide, and the first isolation structure 13 may alternatively be a stacked structure of oxide-nitride-oxide (ONO). Specifically, the material of the first isolation structure 13 is silicon oxide.

In an implementation of the present disclosure, a semiconductor device is disposed in the interposer, and the isolation structure may be located between the deep trench capacitor array 11 and the semiconductor device, or may be located between the deep trench capacitor arrays 11.

It may be understood that, the isolation structure 12 at least partially surrounds the deep trench capacitor 110 on the outmost edge side of the deep trench capacitor array 11. In this way, the deep trench capacitor array 11 can be isolated from another semiconductor device located on the interposer 10, which helps reduce parasitic capacitance between the deep trench capacitor array 11 and the another semiconductor device on the interposer 10, thereby reducing interference caused by the deep trench capacitor array 11 to the another semiconductor device, and improving electrical performance of the semiconductor structure.

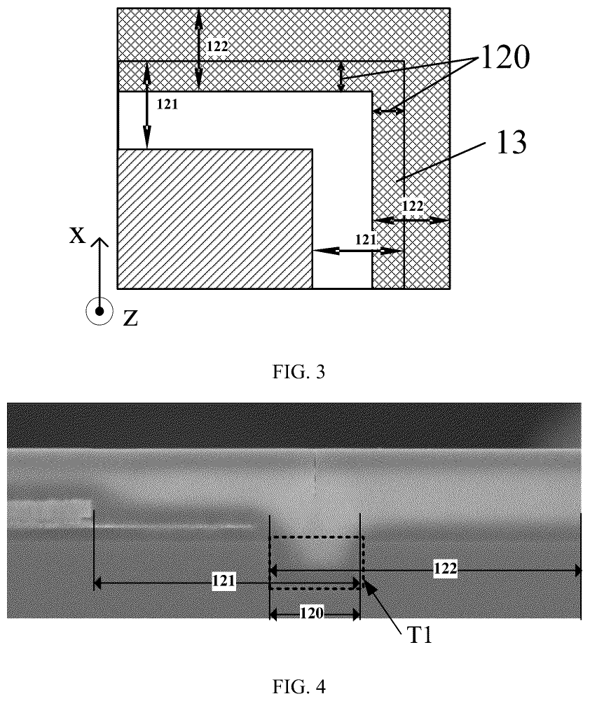

FIG. 4 is a microscopic image of a semiconductor structure according to an embodiment of the present disclosure.

In this embodiment of the present disclosure, referring to FIG. 4, the isolation trench T1 is located in an etching overlapping region 120. Herein, the etching overlapping region 120 is a region in which a first etching region 121 and a second etching region 122 partially overlap. The first etching region 121 and the second etching region 122 are respectively obtained through a first etching and a second etching for forming the deep trench capacitor array 11.

In this embodiment of the present disclosure, referring to FIG. 2 and FIG. 3, on a cross-section perpendicular to the vertical direction z, the first etching region 121, the second etching region 122, and the etching overlapping region 120 each are in a rectangular annular structure. In other words, on the cross-section perpendicular to the vertical direction z, the first isolation structure 13 is a rectangular annular structure. In this way, the first isolation structure 13 can completely surround the deep trench capacitor 110 on the outmost edge side of the deep trench capacitor array 11.

It should be noted that, the first etching region 121, the second etching region 122, and the etching overlapping region 120 herein refer to regions obtained by dividing the plane of the interposer 10, rather than actual regions formed when the interposer 10 is etched. In other words, the first etching region 121, the second etching region 122, and the etching overlapping region 120 are regions that occupy a part of an area on the interposer 10. Details are not described later.

It may be understood that, the etching overlapping region 120 is the region in which the first etching region 121 and the second etching region 122 that are respectively obtained through the first etching and the second etching for forming the deep trench capacitor array 11 partially overlap. Therefore, when the first isolation structure 13 is prepared, two original photomasks required for preparing the deep trench capacitor array 11 may be employed to complete the preparation. No new photomask is required or no new technological process needs to be added during preparation of the first isolation structure 13, so that a preparation process of the first isolation structure is simple and production costs are relatively low.

In some embodiments of the present disclosure, referring to FIG. 1, for the deep trench capacitor array 11, on a side away from the first isolation structure 13, ends of the first electrode layer 111, the capacitor dielectric layer 112, the second electrode layer 113, and the conductive layer 114 that are of the deep trench capacitor 110 on the outmost edge side and that are located on the upper surface of the interposer 10 completely overlap; and
on a side close to the first isolation structure 13, the deep trench capacitor 110 on the outmost edge side exposes a part of the first electrode layer 111, and ends of the capacitor dielectric layer 112, the second electrode layer 113, and the conductive layer 114 that are of the deep trench capacitor 110 on the outmost edge side and that are located on the upper surface of the interposer 10 completely overlap, and the remaining part of the first electrode layer 111 located on the upper surface of the interposer 10 is covered by the capacitor dielectric layer 112.

It may be understood that, in one aspect, the ends of the first electrode layer 111, the capacitor dielectric layer 112, the conductive layer 114, and the second electrode layer 113 that are of the deep trench capacitor 110 and that are located on the interposer 10 are disposed to completely overlap or partially overlap, to improve uniformity of electrode leading-out from the deep trench capacitor 110, thereby reducing parasitic resistance and improving performance of the deep trench capacitor 110. In another aspect, on the side close to the first isolation structure 13, the deep trench capacitor 110 on the outmost edge side exposes a part of the first electrode layer 111, which can facilitate a subsequent electrical connection to a conductive plug.

In some embodiments of the present disclosure, referring to FIG. 1, the semiconductor structure further includes a dielectric material layer 16. The dielectric material layer 16 covers the conductive layer 114 located in the deep trench T0 and completely fills the deep trench T0. Herein, the dielectric material layer 16 can be completely filled in the deep trench T0, which can alleviate a case in a related technology that the deep trench is not completely filled and there is a gap when the deep trench is filled with polysilicon.

In this embodiment of the present disclosure, the material of the dielectric material layer 16 may be at least one of silicon oxide, silicon nitride, and silicon oxynitride. Specifically, the material of the dielectric material layer 16 is silicon oxide.

In some embodiments of the present disclosure, referring to FIG. 1, the semiconductor structure further includes an insulating layer 15. The insulating layer 15 is located between the deep trench capacitor array 11 and the interposer 10 and is exposed on the interposer 10 on a side that is of the deep trench capacitor 110 on the outmost edge side and that is away from the first isolation structure 13. Herein, the insulating layer 15 is located between the deep trench capacitor array 11 and the interposer 10, and is configured to provide electrical isolation between the deep trench capacitor 110 and the interposer 10.

In this embodiment of the present disclosure, the material of the insulating layer 15 may be at least one of insulating materials such as silicon oxide, silicon nitride, and silicon oxynitride. Specifically, the material of the insulating layer 15 is silicon oxide.

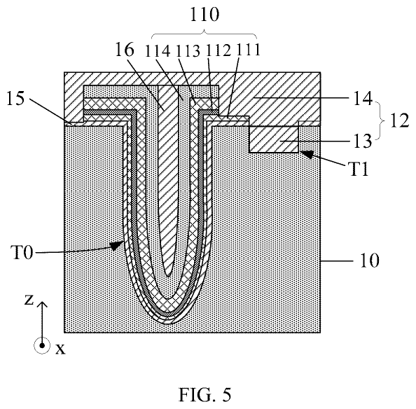

FIG. 5 is a schematic diagram of a vertical cross-section of another semiconductor structure according to an embodiment of the present disclosure.

In some embodiments of the present disclosure, referring to FIG. 5, the isolation structure 12 further includes a second isolation structure 14, and the second isolation structure 14 covers the deep trench capacitor array 11, the first isolation structure 13, and the insulating layer 15 being exposed. In this way, the second isolation structure 14 can isolate the deep trench capacitor array 11 from the outside, to protect the deep trench capacitor array 11.

In this embodiment of the present disclosure, referring to FIG. 5, the material of the second isolation structure 14 may include a material such as an oxide, a nitride, or a nitrogen oxide, and the second isolation structure 14 may alternatively be a stacked structure of oxide-nitride-oxide (ONO). The materials of the second isolation structure 14 and the first isolation structure 13 may be the same or different. Specifically, the material of the second isolation structure 14 is silicon oxide.

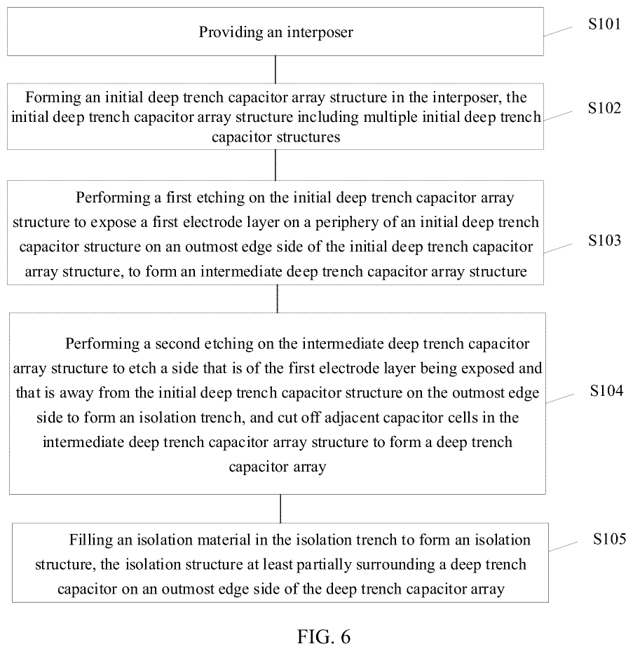

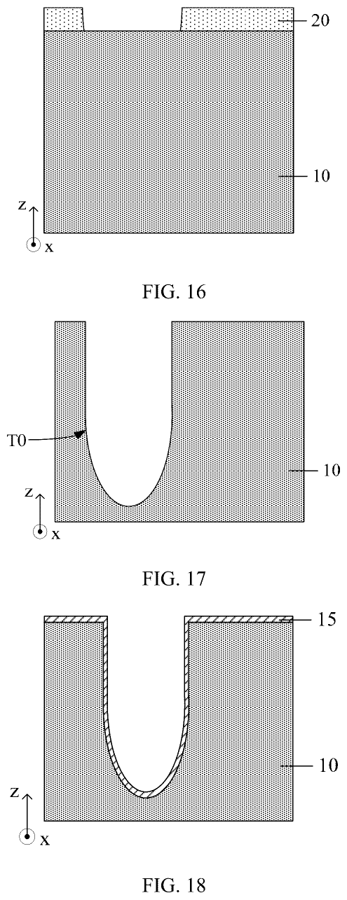

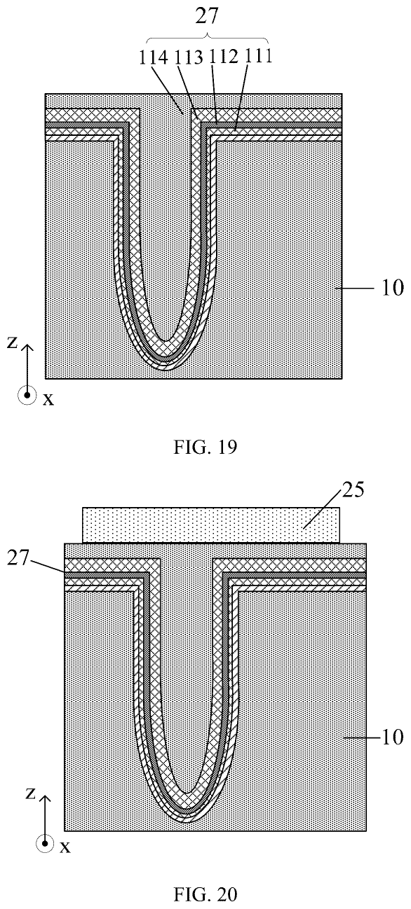

An embodiment of the present disclosure further provides a manufacturing method for a semiconductor structure. FIG. 6 is a schematic flowchart of a manufacturing method for a semiconductor structure according to an embodiment of the present disclosure. As shown in FIG. 6 to FIG. 24, the method includes the steps as follows.

In the step of S101, an interposer 10 is provided.

In the step of S102, an initial deep trench capacitor array structure 23 is formed in the interposer 10, where the initial deep trench capacitor array structure 23 includes multiple initial deep trench capacitor structures 230.

In the step of S103, a first etching is performed on the initial deep trench capacitor array structure 23 to expose a first electrode layer 111 on a periphery of an initial deep trench capacitor structure 230 on an outmost edge side of the initial deep trench capacitor array structure 23, to form an intermediate deep trench capacitor array structure 24.

In the step of S104, a second etching is performed on the intermediate deep trench capacitor array structure 24 to etch a side that is of the first electrode layer 111 being exposed and that is away from the initial deep trench capacitor structure 230 on the outmost edge side to form an isolation trench T1, and cut off adjacent capacitor cells in the intermediate deep trench capacitor array structure 24 to form a deep trench capacitor array 11.

In the step of S105, an isolation material is filled in the isolation trench T1 to form an isolation structure 12, where the isolation structure 12 at least partially surrounds a deep trench capacitor 110 on the outmost edge side of the deep trench capacitor array 11.

FIG. 7 to FIG. 15 are schematic structural diagrams of a semiconductor structure in a manufacturing process according to an embodiment of the present disclosure. With reference to FIG. 7 to FIG. 15, the following further describes the manufacturing method for a semiconductor structure provided in the embodiments of the present disclosure.

First, referring to FIG. 7 to FIG. 10, the step of S101 is performed, that is, an interposer 10 is provided; and the step of S102 is performed, that is, an initial deep trench capacitor array structure 23 is formed in the interposer 10, where the initial deep trench capacitor array structure 23 includes multiple initial deep trench capacitor structures 230.

In this embodiment of the present disclosure, referring to FIG. 7, the interposer 10 is a channel for transferring an electrical signal between multiple chips in a package. The interposer 10 may implement interconnection between chips, or may implement interconnection to a packaging substrate, and serve as a bridge between multiple dies and a circuit board. For example, the interposer 10 may connect a memory chip (e.g., a dynamic random access memory (DRAM)) to a logic chip (e.g., a central processing unit (CPU) or a graphics processing unit (GPU)). The material of the interposer 10 may be a material such as silicon, polysilicon, germanium, silicon germanium, or silicon carbide.

In some embodiments of the present disclosure, referring to FIG. 7 to FIG. 10, that an initial deep trench capacitor array structure 23 is formed in the interposer 10 includes the steps as follows.

A deep trench array is formed in the interposer 10, where the deep trench array includes multiple deep trenches TO.

An insulating material is deposited on the upper surface of the interposer 10 and in the deep trench T0 to form an insulating layer 15, where the insulating layer 15 covers an inner surface of the deep trench T0 and extends to the upper surface of the interposer 10.

A first electrode layer 111, a capacitor dielectric layer 112, a second electrode layer 113, and a conductive layer 114 are sequentially deposited on the insulating layer 15 to form the initial deep trench capacitor array structure 23, where the first electrode layer 111 covers the insulating layer 15, the capacitor dielectric layer 112 covers the first electrode layer 111, the second electrode layer 113 covers the capacitor dielectric layer 112, and the conductive layer 114 covers the second electrode layer 113.

In this embodiment of the present disclosure, a specific step of forming the deep trench array in the interposer 10 includes the steps as follows: A patterned deep trench mask layer 20 (as shown in FIG. 7) is formed on the interposer 10, and the interposer 10 is etched based on the patterned deep trench mask layer 20 to form multiple deep trenches TO (as shown in FIG. 8) to form the deep trench array. Herein, the deep trench T0 has a relatively high aspect ratio. For example, the aspect ratio of the deep trench T0 may be 10, 15, or 20.

In this embodiment of the present disclosure, referring to FIG. 9, the material of the insulating layer 15 may be at least one of silicon oxide, silicon nitride, and silicon oxynitride. Specifically, the material of the insulating layer 15 is silicon oxide. Herein, the insulating layer 15 formed by depositing the insulating material may be configured to provide electrical isolation between the interposer 10 and a subsequently formed deep trench capacitor.

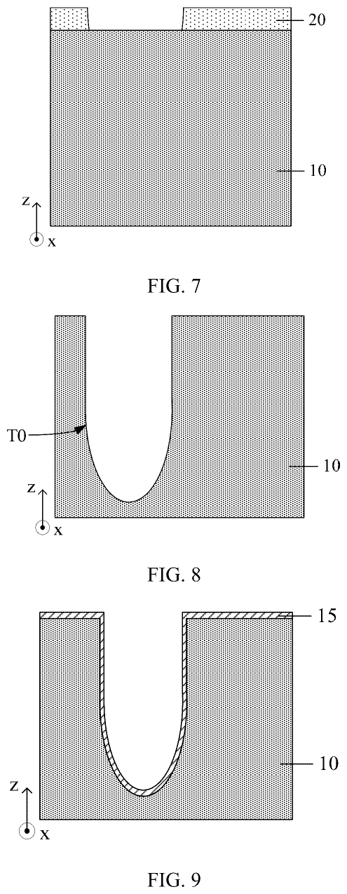

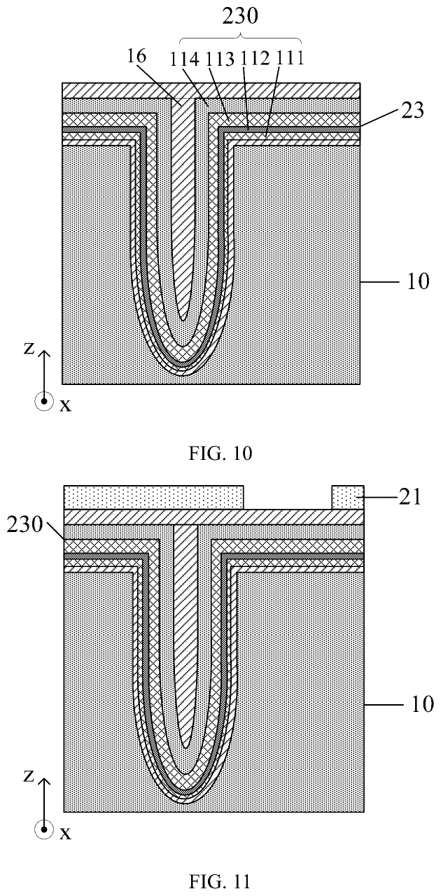

In this embodiment of the present disclosure, referring to FIG. 10, the materials of the first electrode layer 111, the second electrode layer 113, and the conductive layer 114 may be at least one of conductive materials such as doped silicon, polysilicon, copper, tungsten, aluminum, copper alloy, titanium, and titanium nitride. Specifically, the materials of the first electrode layer 111 and the second electrode layer 113 are titanium nitride, and the material of the conductive layer 114 is polysilicon. The material of the capacitor dielectric layer 112 may be at least one of insulating materials such as aluminum oxide (Al₂O₃) and zirconium oxide (ZrO). The capacitor dielectric layer 112 may further include another insulating material with a relatively high dielectric constant (high-k), e.g., a material with a dielectric constant greater than 3.9.

In this embodiment of the present disclosure, the insulating layer 15, the first electrode layer 111, the capacitor dielectric layer 112, the second electrode layer 113, and the conductive layer 114 may be deposited with one or more processes of chemical vapor deposition (CVD), plasma enhanced chemical vapor deposition (PECVD), physical vapor deposition (PVD), and atomic layer deposition (ALD).

In some embodiments of the present disclosure, referring to FIG. 10, after the initial deep trench capacitor array structure 23 is formed in the interposer 10, the method further includes the step as follows: A dielectric material is deposited on the conductive layer 114, where the dielectric material covers the conductive layer 114 in the deep trench T0 and completely fills the deep trench T0 to form a dielectric material layer 16.

Herein, the dielectric material layer 16 can be completely filled in the deep trench T0, which can alleviate a case in a related technology that the deep trench is not completely filled and there is a gap when the deep trench is filled with polysilicon.

In this embodiment of the present disclosure, the material of the dielectric material layer 16 may be at least one of silicon oxide, silicon nitride, and silicon oxynitride. Specifically, the material of the dielectric material layer 16 is silicon oxide.

Next, the step of S103 is performed: A first etching is performed on the initial deep trench capacitor array structure 23 to expose the first electrode layer 111 on a periphery of an initial deep trench capacitor structure 230 on the outmost edge side of the initial deep trench capacitor array structure 23, to form an intermediate deep trench capacitor array structure 24.

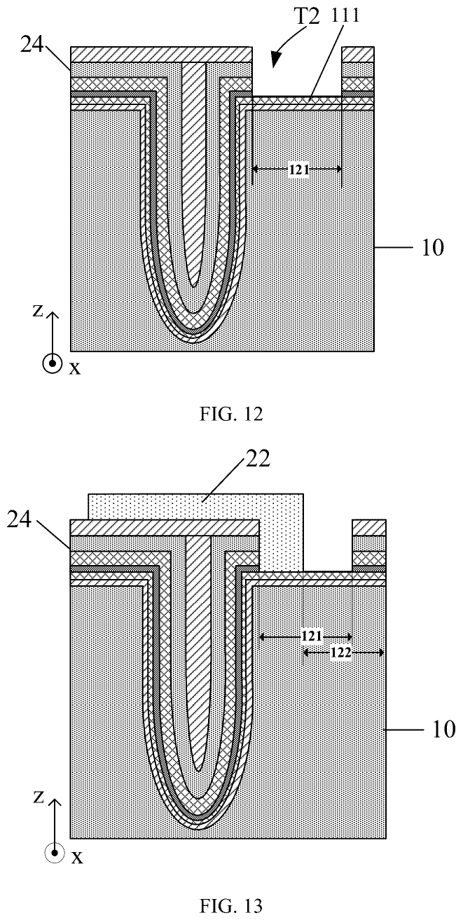

In some embodiments of the present disclosure, referring to FIG. 11 and FIG. 12, that a first etching is performed on the initial deep trench capacitor array structure 23 includes the steps as follows.

A patterned first mask layer 21 is formed on the initial deep trench capacitor array structure 23.

The first etching is performed on the initial deep trench capacitor array structure 23 based on the patterned first mask layer 21 to form a first trench T2 on the periphery of the initial deep trench capacitor structure 230 on the outmost edge side of the initial deep trench capacitor array structure 23, where the first trench T2 exposes the first electrode layer 111, and the remaining initial deep trench capacitor array structure 23 serves as the intermediate deep trench capacitor array structure 24. Herein, a part of the first electrode layer 111 is exposed by the first trench T2, which facilitates electrical connection to a subsequently formed conductive plug.

It should be noted that, the periphery of the initial deep trench capacitor structure 230 on the outmost edge side of the initial deep trench capacitor array structure 23 refers to a region, on a side that is of the initial deep trench capacitor structure 230 and that is away from the initial deep trench capacitor array structure 23, in which a part of the initial deep trench capacitor structure 230 is located on the interposer 10.

In this embodiment of the present disclosure, the initial deep trench capacitor array structure 23 may be etched through plasma etching, or may be etched with other dry etching processes, such as reactive ion etching, sputtering etching, magnetically enhanced reactive ion etching, reactive ion beam etching, or high-density plasma etching.

In this embodiment of the present disclosure, referring to FIG. 12, a first etching region 121 may be obtained by performing the first etching on the initial deep trench capacitor array structure 23 based on the patterned first mask layer 21. The first trench T2 is located in the first etching region 121.

Next, the step of S104 is performed: A second etching is performed on the intermediate deep trench capacitor array structure 24 to etch a side that is of the first electrode layer 111 being exposed and that is away from the initial deep trench capacitor structure 230 on the outmost edge side to form an isolation trench T1, and cut off adjacent capacitor cells in the intermediate deep trench capacitor array structure 24 to form a deep trench capacitor array 11, where the isolation trench T1 is located in the interposer 10 between deep trench capacitor arrays 11.

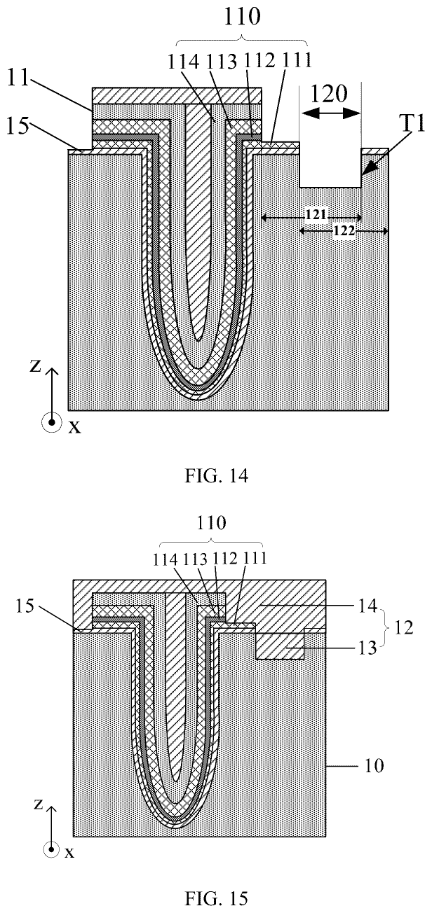

In some embodiments of the present disclosure, referring to FIG. 13 and FIG. 14, that a second etching is performed on the intermediate deep trench capacitor array structure 24 includes the steps as follows.

A patterned second mask layer 22 is formed on the intermediate deep trench capacitor array structure 24.

The second etching is performed on the intermediate deep trench capacitor array structure 24 based on the patterned second mask layer 22 to form the isolation trench T1 on a side that is of the first trench T2 and that is away from the initial deep trench capacitor structure 230 on the outmost edge side, and cut off adjacent capacitor cells in the intermediate deep trench capacitor array structure 24 to expose a part of the insulating layer 15, where the isolation trench T1 extends into the interposer 10, and the remaining intermediate deep trench capacitor array structure 24 serves as the deep trench capacitor array 11.

It should be noted that, herein, the second etching is performed on the intermediate deep trench capacitor array structure 24 to cut off adjacent capacitor cells in the intermediate deep trench capacitor array structure 24 to form the deep trench capacitor array 11 including multiple deep trench capacitors 110. In some other embodiments, the second etching may be further configured to cut off a connection between the deep trench capacitor array 11 and another device. This is not specifically limited herein.

In this embodiment of the present disclosure, referring to FIG. 13, the patterned second mask layer 22 covers a part of the first trench T2, that is, an opening of a first photomask configured to form the patterned first mask layer 21 partially overlaps an opening of a second photomask configured to form the patterned second mask layer 22. Therefore, a second etching region 122 obtained through the second etching partially overlaps the first etching region 121, to form an etching overlapping region 120. Referring to FIG. 14, the isolation trench T1 is located in the etching overlapping region 120.

In this embodiment of the present disclosure, an aspect ratio of the isolation trench T1 is 2 to 10, including endpoint values. For example, the aspect ratio of the isolation trench T1 may be 2, 5, 7, or 10.

FIG. 16 to FIG. 24 are schematic structural diagrams of a semiconductor structure in a manufacturing process according to a related technology. It can be learned from the figures that, in the related technology, the deep trench capacitor array 11 is prepared based on the steps as follows.

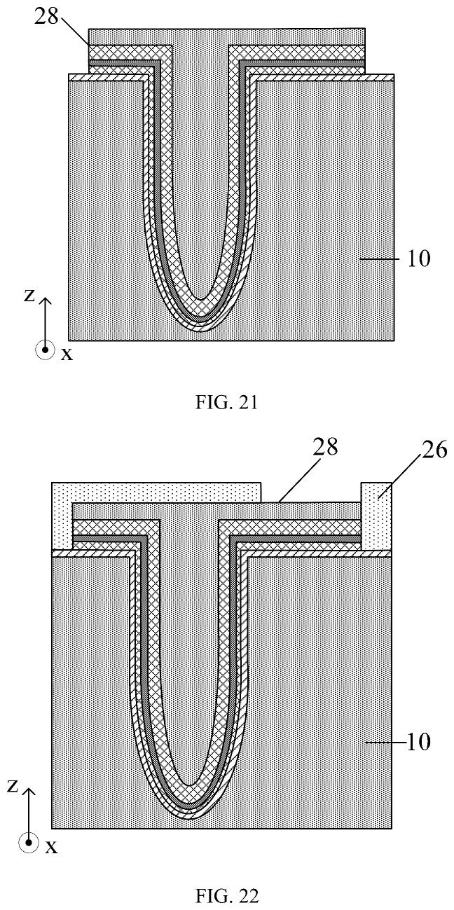

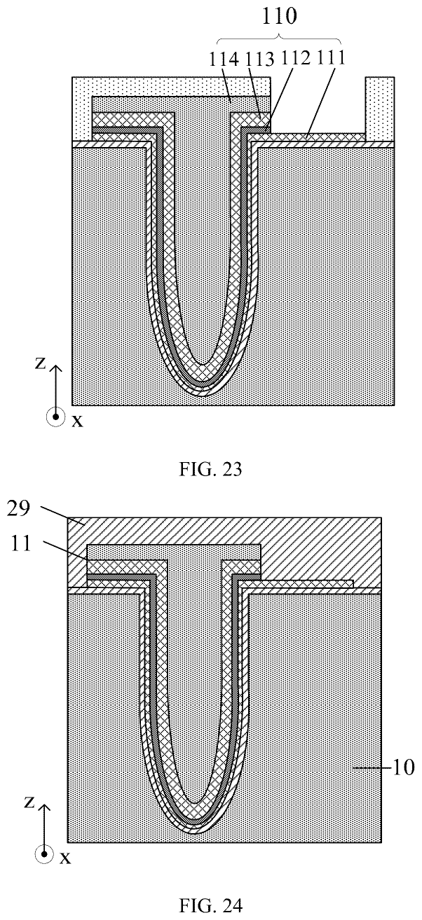

First, an initial capacitor structure 27 is formed on the interposer 10 (as shown in FIG. 16 to FIG. 19). Then, a patterned third mask layer 25 is formed on the initial capacitor structure 27 based on a second photomask, and the initial capacitor structure 27 is etched to form an intermediate capacitor structure 28 (as shown in FIG. 20 and FIG. 21). Next, a patterned fourth mask layer 26 is formed on the intermediate capacitor structure 28 based on a first photomask, and the intermediate capacitor structure 28 is etched to expose a part of the first electrode layer 111 located on the upper surface of the interposer 10 to form the deep trench capacitor array (as shown in FIG. 22 and FIG. 23). Finally, a protective layer 29 (as shown in FIG. 24) is formed on the deep trench capacitor array 11.

Herein, the two photomasks employed in the preparation of the deep trench capacitor array 11 in the present disclosure are the same as the two photomasks employed in the preparation of the deep trench capacitor array 11 in the related technology. However, in the present disclosure, positions of the openings of the first photomask and the second photomask are adjusted to make the openings of the first photomask and the second photomask partially overlap, and the isolation trench T1 can be obtained through etching when the deep trench capacitor array 11 is prepared based on the original two photomasks required for preparing the deep trench capacitor array 11, to subsequently form the first isolation structure 13. In this way, trench isolation between deep trench capacitor arrays 11 can be established without adding additional manufacturing processes.

It may be understood that, the first photomask and the second photomask that are required for preparing the deep trench capacitor array 11 in the related technology are made to partially overlap, so that the original two photomasks are employed to complete preparation of the deep trench capacitor array 11 and subsequent preparation of a first isolation structure 13. No new photomask is required or no new technological process needs to be added during preparation of the first isolation structure 13, so that process steps can be simplified, production costs can be reduced, and production efficiency can be improved.

In addition, in the related technology, when two times of etching processing are performed on the initial capacitor structure 27, an electrode in the capacitor structure is first cut off, and then the first electrode layer 111 that needs to be connected to a conductive plug is exposed. There is no overlapping region between openings of the photomasks employed for the two times of etching herein, that is, there is no overlapping region between the two times of etching, and an electrode cutoff process is completed through one time of etching.

However, in the two times of etching processing in the present disclosure, a part of the first electrode layer 111 is first exposed through the first etching (as shown in FIG. 12), and then during the second etching, the part of the first electrode layer 111 being exposed is cut off (as shown in FIG. 14). In this way, the first electrode layer 111 can be cut off through two-step etching, which can reduce a difficulty in an electrode cutoff process.

In this embodiment of the present disclosure, referring to FIG. 2, projections of the multiple deep trench capacitors 110 on the upper surface of the interposer 10 in a vertical direction z are arranged in a shape of a regular hexagon. In other words, the deep trench capacitors 110 are arranged in a hexagonal closest packed structure. In this way, closely arranged deep trench capacitor arrays 11 can be obtained, thereby increasing a capacitance value of the deep trench capacitor array 11.

In this embodiment of the present disclosure, referring to FIG. 14, for the deep trench capacitor array 11, on a side away from the isolation trench T1, ends of the first electrode layer 111, the capacitor dielectric layer 112, the second electrode layer 113, and the conductive layer 114 that are of a deep trench capacitor 110 on the outmost edge side and that are located on the upper surface of the interposer 10 completely overlap; and on a side close to the isolation trench T1, the deep trench capacitor 110 on the outmost edge side exposes a part of the first electrode layer 111, and ends of the capacitor dielectric layer 112, the second electrode layer 113, and the conductive layer 114 that are of the deep trench capacitor 110 on the outmost edge side and that are located on the upper surface of the interposer 10 completely overlap, and the remaining part of the first electrode layer 111 located on the upper surface of the interposer 10 is covered by the capacitor dielectric layer 112.

It may be understood that, the ends of the first electrode layer 111, the capacitor dielectric layer 112, the conductive layer 114, and the second electrode layer 113 that are of the deep trench capacitor 110 and that are located on the interposer 10 are disposed to completely overlap or partially overlap, to improve uniformity of electrode leading-out from the deep trench capacitor 110, thereby reducing parasitic resistance and improving performance of the deep trench capacitor 110.

Finally, the step of S105 is performed: An isolation material is filled in the isolation trench T1 to form an isolation structure 12, where the isolation structure 12 at least partially surrounds the deep trench capacitor 110 on the outmost edge side of the deep trench capacitor array 11.

In some embodiments of the present disclosure, referring to FIG. 15, that an isolation material is filled in the isolation trench T1 to form an isolation structure 12 includes the step as follows.

The isolation material is deposited on the interposer 10 on which the deep trench capacitor array 11 is formed, where a part of the isolation material completely fills the isolation trench T1 to form a first isolation structure 13, a part of the isolation material covers the deep trench capacitor array 11, the first isolation structure 13, and the insulating layer 15 being exposed to form a second isolation structure 14, and the first isolation structure 13 and the second isolation structure 14 form the isolation structure 12.

It may be understood that, the first isolation structure 13 and the second isolation structure 14 are simultaneously formed by depositing the isolation material on the interposer 10, which helps simplify a process and reduce a preparation difficulty and production costs. In this embodiment of the present disclosure, the isolation structure 12 may partially surround the deep trench capacitor 110 on the outmost edge side of the deep trench capacitor array 11, or may completely surround the deep trench capacitor 110 on the outmost edge side of the deep trench capacitor array 11.

In this embodiment of the present disclosure, referring to FIG. 15, on a cross-section perpendicular to a first direction x, a cross-sectional shape of the first isolation structure 13 may be a rectangle, a trapezoid, an inverted trapezoid, or an oval. This is not specifically limited herein.

In this embodiment of the present disclosure, referring to FIG. 15, the materials of the first isolation structure 13 and the second isolation structure 14 may include a material such as an oxide, a nitride, or a nitrogen oxide. Specifically, the materials of the first isolation structure 13 and the second isolation structure 14 are silicon oxide.

It should be noted that, in some other embodiments, the first isolation structure 13 and the second isolation structure 14 may alternatively be formed by two deposition processes, and the first isolation structure 13 and the second isolation structure 14 may be prepared by selecting different materials based on an actual requirement.

It should be noted that, the semiconductor structure and the manufacturing method therefor provided in the embodiments of the present disclosure may be applied to a DRAM structure or another semiconductor device. No further limitation is imposed herein. The embodiments of the semiconductor structure and the embodiments of the manufacturing method for a semiconductor structure provided in the present disclosure belong to the same concept. The technical features in the technical solutions described in the embodiments may be arbitrarily combined when there is no conflict.

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A semiconductor structure, comprising:
an interposer comprising a deep trench capacitor array and an isolation structure, wherein
the deep trench capacitor array comprises a plurality of deep trench capacitors, and the isolation structure at least partially surrounding a deep trench capacitor on an outmost edge side of the deep trench capacitor array.

2. The semiconductor structure according to claim 1, wherein
each of the deep trench capacitors comprises a first electrode layer, a capacitor dielectric layer, a second electrode layer, and a conductive layer, wherein
the first electrode layer covers an inner surface of a deep trench in the interposer and extends to an upper surface of the interposer, the capacitor dielectric layer covers the first electrode layer, the second electrode layer covers the capacitor dielectric layer, and the conductive layer covers the second electrode layer.

3. The semiconductor structure according to claim 2, wherein the isolation structure comprises a first isolation structure, an isolation trench is disposed in the interposer, and the first isolation structure is located in the isolation trench; and for the deep trench capacitor array,
on a side away from the first isolation structure, ends of the first electrode layer, the capacitor dielectric layer, the second electrode layer, and the conductive layer that are of the deep trench capacitor on the outmost edge side and that are located on the upper surface of the interposer completely overlap; and
on a side close to the first isolation structure, the deep trench capacitor on the outmost edge side exposes a part of the first electrode layer, ends of the capacitor dielectric layer, the second electrode layer, and the conductive layer that are of the deep trench capacitor on the outmost edge side and that are located on the upper surface of the interposer completely overlap, and a remaining part of the first electrode layer located on the upper surface of the interposer is covered by the capacitor dielectric layer.

4. The semiconductor structure according to claim 3, wherein
the semiconductor structure further comprises a dielectric material layer, and the dielectric material layer covers the conductive layer located in the deep trench and completely fills the deep trench.

5. The semiconductor structure according to claim 3, wherein
the semiconductor structure further comprises an insulating layer, and the insulating layer is located between the deep trench capacitor array and the interposer and is exposed on the interposer on a side that is of the deep trench capacitor on the outmost edge side and that is away from the first isolation structure.

6. The semiconductor structure according to claim 5, wherein
the isolation structure further comprises a second isolation structure, and the second isolation structure covers the deep trench capacitor array, the first isolation structure, and the insulating layer being exposed.

7. The semiconductor structure according to claim 3, wherein
on a cross-section perpendicular to a first direction, a cross-sectional shape of the first isolation structure is a rectangle, a trapezoid, an inverted trapezoid, or an oval, and the first direction is perpendicular to a vertical direction.

8. The semiconductor structure according to claim 3, wherein
an aspect ratio of the isolation trench is 2 to 10.

9. The semiconductor structure according to claim 1, wherein
projections of the plurality of deep trench capacitors on an upper surface of the interposer in the vertical direction are arranged in a shape of a regular hexagon.

10. A manufacturing method for a semiconductor structure, comprising:
providing an interposer;
forming an initial deep trench capacitor array structure in the interposer, the initial deep trench capacitor array structure comprising a plurality of initial deep trench capacitor structures;
performing a first etching on the initial deep trench capacitor array structure to expose a first electrode layer on a periphery of an initial deep trench capacitor structure on an outmost edge side of the initial deep trench capacitor array structure, to form an intermediate deep trench capacitor array structure;
performing a second etching on the intermediate deep trench capacitor array structure to etch a side that is of the first electrode layer being exposed and that is away from the initial deep trench capacitor structure on the outmost edge side to form an isolation trench, and cut off adjacent capacitor cells in the intermediate deep trench capacitor array structure to form a deep trench capacitor array; and
filling an isolation material in the isolation trench to form an isolation structure, the isolation structure at least partially surrounding a deep trench capacitor on an outmost edge side of the deep trench capacitor array.

11. The manufacturing method for a semiconductor structure according to claim 10, wherein the forming an initial deep trench capacitor array structure in the interposer comprises:
forming a deep trench array in the interposer, the deep trench array comprising a plurality of deep trenches;
depositing an insulating material on an upper surface of the interposer and in each of the deep trenches to form an insulating layer, the insulating layer covering an inner surface of the deep trench and extends to the upper surface of the interposer; and
sequentially depositing the first electrode layer, a capacitor dielectric layer, a second electrode layer, and a conductive layer on the insulating layer to form the initial deep trench capacitor array structure, the first electrode layer covering the insulating layer, the capacitor dielectric layer covering the first electrode layer, the second electrode layer covering the capacitor dielectric layer, and the conductive layer covering the second electrode layer.

12. The manufacturing method for a semiconductor structure according to claim 11, after the forming an initial deep trench capacitor array structure in the interposer, comprising:
depositing a dielectric material on the conductive layer, the dielectric material covering the conductive layer in the deep trench and completely filling the deep trench to form a dielectric material layer.

13. The manufacturing method for a semiconductor structure according to claim 11, wherein the performing a first etching on the initial deep trench capacitor array structure comprises:
forming a patterned first mask layer on the initial deep trench capacitor array structure; and
performing the first etching on the initial deep trench capacitor array structure based on the patterned first mask layer to form a first trench on the periphery of the initial deep trench capacitor structure on the outmost edge side of the initial deep trench capacitor array structure, the first trench exposing the first electrode layer, and a remaining initial deep trench capacitor array structure serving as the intermediate deep trench capacitor array structure.

14. The manufacturing method for a semiconductor structure according to claim 13, wherein the performing a second etching on the intermediate deep trench capacitor array structure comprises:
forming a patterned second mask layer on the intermediate deep trench capacitor array structure; and
performing the second etching on the intermediate deep trench capacitor array structure based on the patterned second mask layer to form the isolation trench on a side that is of the first trench and that is away from the initial deep trench capacitor structure on the outmost edge side, and cut off adjacent capacitor cells in the intermediate deep trench capacitor array structure to expose a part of the insulating layer, the isolation trench extending into the interposer, and a remaining intermediate deep trench capacitor array structure serving as the deep trench capacitor array.

15. The manufacturing method for a semiconductor structure according to claim 14, wherein the filling an isolation material in the isolation trench to form an isolation structure comprises:
depositing the isolation material on the interposer on which the deep trench capacitor array is formed, a part of the isolation material completely filling the isolation trench to form a first isolation structure, a part of the isolation material covering the deep trench capacitor array, the first isolation structure, and the insulating layer being exposed to form a second isolation structure, and the first isolation structure and the second isolation structure forming the isolation structure.
